(19) United States
(12) Patent Application Publication
(10) Pub. No.: US 2021/0059042 A1
(43) Pub. Date: Feb. 25, 2021

(54) Electromagnetic Shielding Film and Shielded Printed Wiring Board Including the Same

(71) Applicant: Tatsuta Electric Wire & Cable Co., Ltd., Higashiosaka-shi, Osaka (JP)

(72) Inventors: Sirou YAMAUCHI, Kizugawa-shi, Kyoto (JP); Masahiro WATANABE, Kizugawa-shi, Kyoto (JP); Hiroshi TAJIMA, Kizugawa-shi, Kyoto (JP)

(21) Appl. No.: 16/626,436

(22) PCT Filed: Jul. 10, 2017
(86) PCT No.: PCT/JP2017/025173

§ 371 Date: Dec. 24, 2019

(51) Int. Cl. H05K 1/02; H05K 9/00; H01J 11/44

(52) U.S. Cl. CPC H05K 1/0218; H01J 2211/446; H01J 11/44; H05K 9/0075

(57) ABSTRACT

It is an object of the present invention to provide an electromagnetic shielding film having excellent high frequency signal transmission characteristics and excellent shielding characteristics against electromagnetic waves in a high frequency region and a shielded printed wiring board including the same. An electromagnetic shielding film 1 includes a shielding layer that is formed by a first metal layer mainly comprised of nickel and a second metal layer mainly comprised of copper, an adhesive layer formed on the second metal layer side of the shielding layer, and a protective layer formed on the first metal layer side of the shielding layer which is the opposite side of the shielding layer from the second metal layer side. The first metal layer has a thickness T₁ of 2 μm or more and 10 μm or less, and the second metal layer has a thickness T₂ of 2 μm or more and 10 μm or less.

### TECHNICAL FIELD

The present disclosure relates to electromagnetic shielding films and shielded printed wiring boards including the same.

### BACKGROUND ART

In recent years, smartphones and tablet information terminals have been required to have the ability to transmit large amounts of data at high speed. High frequency signals need be used to transmit large amounts of data at high speed. However, the use of high frequency signals tends to cause malfunction of peripheral devices due to electromagnetic noise generated from a signal circuit mounted on a printed wiring board. In order to prevent such malfunction, it is important to shield the printed wiring board from electromagnetic waves.

A method using an electromagnetic shielding film having a shielding layer and a conductive adhesive layer has been proposed as a method of shielding a printed wiring board. More specifically, for example, electromagnetic shielding films have been proposed in which a first metal layer and a second metal layer, each mainly comprised of nickel or copper, are sequentially formed on one surface of an insulating layer (see, e.g., Patent Documents 1 and 2).

In these electromagnetic shielding films, a conductive adhesive layer is placed over openings formed in an insulating layer covering a ground circuit of a printed wiring board and is heated and pressed to fill the openings with the conductive adhesive. A shielding layer is thus connected to the ground circuit of the printed wiring board via the conductive adhesive, whereby the printed wiring board is shielded.

### CITATION LIST

### Patent Document

PATENT DOCUMENT 1: Japanese Unexamined Patent Publication (Japanese Translation of PCT Application) No. 2015-523709

PATENT DOCUMENT 2: WO2009/019963

### SUMMARY OF THE INVENTION

### Technical Problem

In the case where two metal layers are formed as in the electromagnetic shielding films described in Patent Documents 1 and 2, high frequency signal transmission characteristics may be degraded.

Increasing the thickness of the shielding layer improves shielding characteristics against electromagnetic waves in a high frequency region (1 GHz to 10 GHz) but makes it difficult to achieve reduction in thickness of electromagnetic shielding films.

The present invention was developed in view of the above problems, and it is an object of the present invention to provide an electromagnetic shielding film having excellent high frequency signal transmission characteristics and excellent shielding characteristics against electromagnetic waves in the high frequency region and a shielded printed wiring board including the electromagnetic shielding film.

### Solution to the Problem

In order to achieve the above object, an electromagnetic shielding film of the present invention includes a shielding layer that is formed by a first metal layer mainly comprised of nickel and a second metal layer mainly comprised of copper, an adhesive layer formed on the second metal layer side of the shielding layer, and a protective layer formed on the first metal layer side of the shielding layer which is an opposite side of the shielding layer from the second metal layer side, and is characterized in that the first metal layer has a thickness of 2 μm or more and 10 μm or less, and the second metal layer has a thickness of 2 μm or more and 10 μm or less.

### Advantages of the Invention

According to the present invention, an electromagnetic shielding film can be provided which has excellent high frequency signal transmission characteristics and excellent shielding characteristics against electromagnetic waves in a high frequency region.

### BRIEF DESCRIPTION OF THE DRAWINGS

FIG. 1 is a sectional view of an electromagnetic shielding film according to an embodiment of the present invention.

FIG. 2 is a sectional view of a shielded printed wiring board according to an embodiment of the present invention.

FIG. 3 is a sectional view of a shielded printed wiring board according to a modification of the present invention.

FIG. 4 is a diagram showing the configuration of a system that is used in a KEC method for use in examples.

FIG. 5 is a diagram showing the configuration of the system that is used in the KEC method for use in the examples.

FIG. 6 is a graph showing the measurement results of electric field shielding performance by the KEC method.

FIG. 7 is a graph showing the measurement results of magnetic field shielding performance by the KEC method.

FIG. 8 is a diagram showing the configuration of a system for measuring output waveform characteristics which is used in the examples.

FIG. 9 is a diagram showing the results of output waveforms observed with an oscilloscope.

### DESCRIPTION OF EMBODIMENTS

An electromagnetic shielding film of the present invention will be specifically described below. The present invention is not limited to the following embodiments and may be modified as appropriate without departing from the spirit and scope of the present invention.

<Electromagnetic Shielding Film>

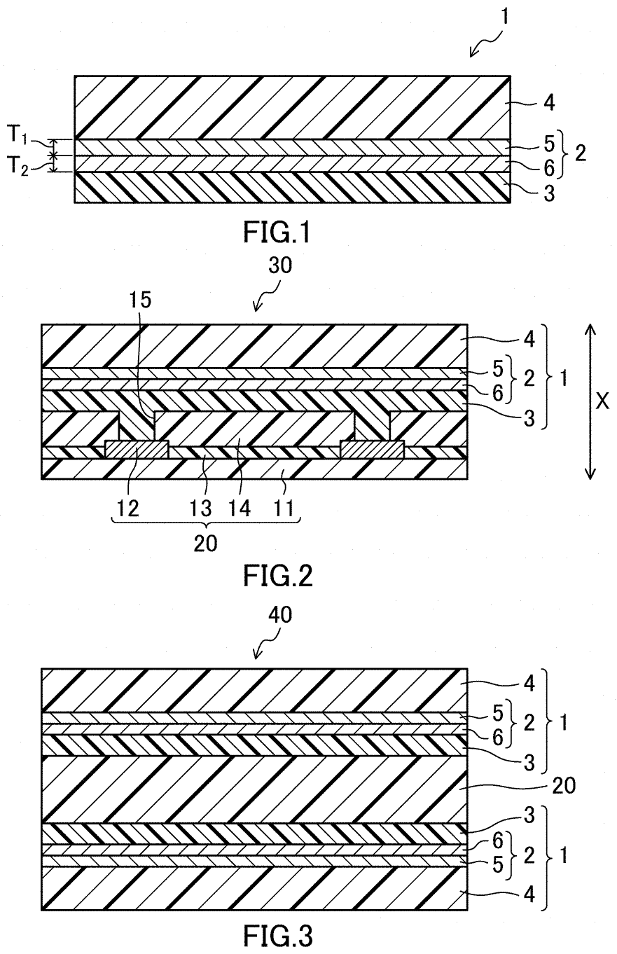

As shown in FIG. 1, an electromagnetic shielding film 1 of the present invention includes a shielding layer 2, an adhesive layer 3 formed on the first surface side of the shielding layer 2, and a protective layer 4 formed on the second surface side of the shielding layer 2 which is the opposite side of the shielding layer 2 from the first surface.

The electromagnetic shielding film 1 of the present invention can be used for signal transmission systems that transmit frequency signals in a high frequency region (1 GHz to 10 GHz) and can provide both high frequency signal transmission characteristics and shielding characteristics against electromagnetic waves in the high frequency region.

<Shielding Layer>

As shown in FIG. 1, the shielding layer 2 is formed by a first metal layer 5 formed on one surface of the protective layer 4 and a second metal layer 6 formed on a surface of the first metal layer 5.

The first metal layer 5 and the second metal layer 6 can be metal films, conductive films comprised of conductive particles, etc. In the present embodiment, the first metal layer 5 is mainly comprised of nickel, and the second metal layer 6 is mainly comprised of copper.

In the present embodiment, the thickness T₁ of the first metal layer 5 mainly comprised of nickel is set to 2 μm or more and 10 μm or less. In the case where the thickness T₁ is smaller than 2 μm, shielding characteristics against electromagnetic waves in the high frequency region may be degraded. In the case where the thickness T₁ is larger than 10 μm, it is difficult to achieve reduction in thickness and the cost may increase.

In order to improve the shielding characteristics against a high frequency electromagnetic field and achieve reduction in circuit thickness and in view of cost, it is preferable that the thickness T₁ of the first metal layer 5 be 6 μm or less.

In the present embodiment, the thickness T₂ of the second metal layer 6 mainly comprised of copper is set to 2 μm or more and 10 μm or less. In the case where the thickness T₂ is smaller than 2 μm, the transmission characteristics in the high frequency region may be degraded. In the case where the thickness T₂ is larger than 10 μm, it is difficult to achieve reduction in thickness and the cost may increase.

In order to achieve reduction in thickness of the electromagnetic shielding film and restrain an increase in cost, it is preferable that the thickness T₂ of the second metal layer 6 be 6 μm or less.

As described above, in the electromagnetic shielding film 1 of the present invention, the thickness T₁ of the first metal layer mainly comprised of nickel is set to 2 μm or more and 10 μm or less, and the thickness T₂ of the second metal layer 6 mainly comprised of copper is set to 2 μm or more and 10 μm or less. Accordingly, the electromagnetic shielding film 1 can be obtained which has excellent high frequency signal transmission characteristics and excellent shielding characteristics against electromagnetic waves in the high frequency region.

In the present embodiment, it is preferable that the sum of the thickness T₁ of the first metal layer 5 and the thickness T₂ of the second metal layer 6 be 4 μm or more and 20 μm or less (i.e., 4 μm≤T₁+T₂≤20 μm). In the case where the sum of the thicknesses is smaller than 4 μm, the shielding characteristics against electromagnetic waves in the high frequency region may be degraded. In view of the electromagnetic shielding characteristics, the larger the sum of the thicknesses is, the more preferable. However, in the case where the sum of the thicknesses is larger than 20 μm, it is difficult to achieve reduction in thickness and the cost may increase.

<Adhesive Layer>

As shown in FIG. 1, the adhesive layer 3 is formed on the second metal layer 6 side of the shielding layer 2. The adhesive layer 3 is not particularly limited as long as it can fix the electromagnetic shielding film 1 to a printed wiring board. However, it is preferable that the adhesive layer 3 be a conductive adhesive layer comprised of an adhesive resin composition and a conductive filler. The use of such a conductive adhesive layer allows a printed circuit (ground circuit) to be reliably connected to the shielding layer 2.

The conductive adhesive layer may be an anisotropic conductive adhesive layer with low conductive filler content. In the case where such an anisotropic conductive adhesive layer is used, the adhesive layer 3 has a smaller thickness as compared to the case where an isotropic conductive adhesive layer is used. Moreover, since the anisotropic conductive adhesive layer contains a small amount of conductive filler, a flexible adhesive layer 3 can be obtained.

The adhesive resin composition is not particularly limited, but may be a thermoplastic resin composition such as a styrene resin composition, a vinyl acetate resin composition, a polyester resin composition, a polyethylene resin composition, a polypropylene resin composition, an imide resin composition, an amide resin composition, or an acrylic resin composition, a thermosetting resin composition such as a phenolic resin composition, an epoxy resin composition, a urethane resin composition, a melamine resin composition, or an alkyd resin composition, etc. These resin compositions may be used alone or two or more of the resin compositions may be combined.

The adhesive layer 3 may contain at least one of a curing accelerator, a tackifier, an antioxidant, a pigment, a dye, a plasticizer, an ultraviolet absorber, an antifoaming agent, a leveling agent, a filler, a flame retardant, a viscosity modifier, etc. as necessary.

Although the thickness of the adhesive layer 3 is not particularly limited and can be set as necessary, the thickness of the adhesive layer 3 may be 3 μm or more, preferably 4 μm or more, and 10 μm or less, preferably 7 μm or less.

The conductive filler is not particularly limited, but for example, may be a metal filler, a metal-coated resin filler, a carbon filler, or a mixture thereof. Examples of the metal filler are copper powder, silver powder, nickel powder, silver-coated copper powder, gold-coated copper powder, silver-coated nickel powder, and gold-coated nickel powder. These metal powders can be produced by an electrolytic process, an atomization process, or a reduction process.

Especially in order to facilitate contact between the fillers, it is preferable that the average particle size of the conductive filler be 3 to 50 μm. The conductive filler may be in the form of spheres, flakes, dendrites, fibers, etc. In view of connection resistance and cost, it is preferable that the conductive filler be at least one selected from the group consisting of silver powder, silver-coated copper powder, and copper powder.

It is preferable that the conductive filler content in the anisotropic conductive adhesive layer be 3 mass % to 39 mass %. The conductive filler content in this range can provide satisfactory electromagnetic shielding characteristics and transmission characteristics in the high frequency region.

<Protective Layer>

As shown in FIG. 1, the protective layer 4 is formed on the first metal layer 5 side of the shielding layer 2 which is the opposite side of the shielding layer 2 from the second metal layer 6 side. The protective layer 4 need only have predetermined mechanical strength, chemical resistance, heat resistance, etc. which are high enough to protect the shielding layer 2. The protective layer 4 is not particularly limited as long as it has sufficient insulating properties and can protect the adhesive layer 3 and the shielding layer 2, but for example, may be comprised of a thermoplastic resin composition, a thermosetting resin composition, an active energy ray-curable composition, etc.

The thermoplastic resin composition is not particularly limited, but may be a styrene resin composition, a vinyl acetate resin composition, a polyester resin composition, a polyethylene resin composition, a polypropylene resin composition, an imide resin composition, an acrylic resin composition, etc. The thermosetting resin composition is not particularly limited, but may be a phenolic resin composition, an epoxy resin composition, a urethane resin composition with an isocyanate group at its terminal, a urea resin with an isocyanate group at its terminal, a urethane-urea resin with an isocyanate group at its terminal, a melamine resin composition, an alkyd resin composition, etc. The active energy ray-curable composition is not particularly limited, but for example, may be a polymerizable compound having at least two (meth)acryloyloxy groups in a molecule, etc. These resins may be used alone or two or more of the resins may be combined.

In order to improve reflow resistance and reduce or eliminate the possibility of degradation in electrical connection between the electromagnetic shielding film 1 and the printed wiring board, it is preferable that the protective layer 4 be comprised of a urethane-urea resin with an isocyanate group at its terminal or a mixture of a urethane-urea resin with an isocyanate group at its terminal and an epoxy resin. A urethane resin with an isocyanate group at its terminal or a urethane-urea resin with an isocyanate group at its terminal preferably has an acid value of 1 to 30 mgKOH/g, more preferably 3 to 20 mgKOH/g. Two or more of urethane resins and urethane-urea resins which have an acid value in the range of 1 to 30 mgKOH/g and have different acid values from each other may be combined. In the case where the acid value is 1 mgKOH/g or more, the electromagnetic shielding film has satisfactory reflow resistance. In the case where the acid value is 30 mgKOH/g or less, the electromagnetic shielding film has satisfactory bending resistance. The acid value is measured in accordance with JIS K 0070-1992. The protective layer 4 may be made of either a single material or two or more materials.

The protective layer 4 may contain at least one of a curing accelerator, a tackifier, an antioxidant, a pigment, a dye, a plasticizer, an ultraviolet absorber, an antifoaming agent, a leveling agent, a filler, a flame retardant, a viscosity modifier, an anti-blocking agent, etc. as necessary.

The protective layer 4 may be a laminate of two or more layers comprised of different materials or having different physical properties such as hardness or elastic modulus from each other. For example, in the case where the protective layer 4 is a laminate of an outer layer having low hardness and an inner layer having high hardness, the outer layer has a cushioning effect, which can reduce the pressure that is applied to the shielding layer 2 in the process of heating and pressing the electromagnetic shielding film 1 against the printed wiring board. This can restrain the shielding layer 2 from being destroyed by stepped portions of the printed wiring board.

Although the thickness of the protective layer 4 is not particularly limited and can be set as necessary, the thickness of the protective layer 4 may be 1 μm or more, preferably 4 μm or more, and 20 μm or less, preferably 10 μm or less, more preferably 5 μm or less. The protective layer 4 with a thickness of 1 μm or more can sufficiently protect the adhesive layer 3 and the shielding layer 2. The protective layer 4 with a thickness of 20 μm or less allows the electromagnetic shielding film 1 to have sufficient bendability. A single electromagnetic shielding film 1 can thus be easily applied to members for which bendability is required.

(Manufacturing Method of Electromagnetic Shielding Film)

Next, an example of a manufacturing method of the electromagnetic shielding film 1 of the present invention will be described. The manufacturing method of the electromagnetic shielding film 1 of the present invention is not particularly limited, but for example, may be a method including the steps of: forming the protective layer 4; forming the first metal layer 5 on a surface of the protective layer 4; forming the second metal layer 6 on the opposite surface of the first metal layer 5 from the protective layer 4; and coating the opposite surface of the second metal layer 6 from the first metal layer 5 with an adhesive layer composition and then curing the adhesive layer composition to form the adhesive layer 3.

<Protective Layer Forming Step>

First, a protective layer composition is prepared. The protective layer composition can be prepared by adding appropriate amounts of solvent and other compounding agent(s) to a resin composition. Examples of the solvent include toluene, acetone, methyl ethyl ketone, methanol, ethanol, propanol, and dimethylformamide. A crosslinking agent, a polymerization catalyst, a curing accelerator, a coloring agent, etc. may be added as other compounding agent(s). The compounding agent(s) is added as necessary.

Next, one surface of a support base material is coated with the prepared protective layer composition. A method for coating one surface of the support base material with the protective layer composition is not particularly limited, and a known technique such as lip coating, comma coating, gravure coating, or slot die coating may be used.

For example, the support base material may be in the form of a film. The support base material is not particularly limited, and for example, may be made of a polyolefin material, a polyester material, a polyimide material, a polyphenylene sulfide material, etc. A release agent layer may be formed between the support base material and the protective layer composition.

After the support base material is coated with the protective layer composition, the coated support base material is heated and dried to remove the solvent. The protective layer 4 is thus formed. The support base material can be separated from the protective layer 4. Such separation of the support base material can be performed after the electromagnetic shielding film 1 is bonded to a printed wiring board. This allows the electromagnetic shielding film 1 to be protected by the support base material.

<First Metal Layer Forming Step>

The first metal layer 5 mainly comprised of nickel is then formed on a surface of the protective layer 4. More specifically, the first metal layer 5 can be formed by placing a film in a batch vacuum deposition system (made by ULVAC, Inc., EBH-800) with a 50 mm by 500 mm nickel target, evacuating the system to an ultimate vacuum of 5×10⁻¹ Pa or less in an argon gas atmosphere, and continuously applying a DC power supply for a time sufficient to form a metal film with a predetermined thickness. The sputtering is immediately followed by vacuum deposition for forming the second metal layer 6 so that there is no contact with the atmosphere between the sputtering and the deposition.

Since the first metal layer 5 is formed by sputtering, the first metal layer 5 has sufficient adhesion to the protective layer 4. Since nickel is used for the first metal layer 5, the average grain size of the second metal layer 6 can be reduced and surface oxidation of the second metal layer 6 can be restrained.

<Second Metal Layer Forming Step>

Subsequently, the second metal layer 6 mainly comprised of copper is formed on the opposite surface of the first metal layer 5 from the protective layer 4. More specifically, vacuum deposition is performed by first placing a film in a batch vacuum deposition system (made by ULVAC, Inc., EBH-800), then placing on an evaporation boat an amount of copper sufficient to form a film with a target thickness, and subsequently evacuating the system to an ultimate vacuum of 9.0×10⁻³ Pa or less and heating the evaporation boat.

Vacuum deposition is preferably used to form the second metal layer with a small average grain size. With sputtering etc., it is difficult to control the average grain size to 200 nm or less due to a high metal crystal growth rate. It is therefore preferable to form the second metal layer 6 by vacuum deposition.

<Adhesive Layer Forming Step>

Subsequently, the opposite surface of the second metal layer 6 from the first metal layer 5 is coated with an adhesive layer composition to form the adhesive layer 3. The adhesive layer composition contains a resin composition and a solvent. The resin composition is not particularly limited, but may be a thermoplastic resin composition such as a styrene resin composition, a vinyl acetate resin composition, a polyester resin composition, a polyethylene resin composition, a polypropylene resin composition, an imide resin composition, an amide resin composition, or an acrylic resin composition, a thermosetting resin composition such as a phenolic resin composition, an epoxy resin composition, a urethane resin composition, a melamine resin composition, or an alkyd resin composition, etc. These resin compositions may be used alone or two or more of the resin compositions may be combined.

Examples of the solvent include toluene, acetone, methyl ethyl ketone, methanol, ethanol, propanol, and dimethylformamide.

The adhesive layer composition may contain at least one of a curing accelerator, a tackifier, an antioxidant, a pigment, a dye, a plasticizer, an ultraviolet absorber, an antifoaming agent, a leveling agent, a filler, a flame retardant, a viscosity modifier, etc. as necessary. The proportion of the resin component in the adhesive layer composition is determined as appropriate according to the thickness of the adhesive layer 3 etc.

A method for coating the second metal layer 6 with the adhesive layer composition is not particularly limited, and lip coating, comma coating, gravure coating, slot die coating, etc. may be used.

After the second metal layer 6 is coated with the adhesive layer composition, the coated metal layer 6 is heated and dried to remove the solvent. The adhesive layer 3 is thus formed. A release film may be bonded to a surface of the adhesive layer 3 as necessary.

(Shielded Printed Wiring Board)

For example, the electromagnetic shielding film 1 of the present embodiment can be used for a shielded printed wiring board 30 shown in FIG. 2. The shielded printed wiring board 30 includes a printed wiring board 20 and the electromagnetic shielding film 1.

The printed wiring board 20 has a base layer 11, a printed circuit (ground circuit) 12 formed on the base layer 11, an insulating adhesive layer 13 formed on the base layer 11 so as to adjoin the printed circuit 12, and an insulating cover lay 14 having openings 15 that expose a part of the printed circuit 12 and covering the insulating adhesive layer 13. The insulating adhesive layer 13 and the cover lay 14 form an insulating layer of the printed wiring board 20.

The base layer 11, the insulating adhesive layer 13, and the cover lay 14 are not particularly limited, but may be resin films etc. In this case, the base layer 11, the insulating adhesive layer 13, and the cover lay 14 may be comprised of a resin such as polypropylene, cross-liked polyethylene, polyester, polybenzimidazole, polyimide, polyimide-amide, polyetherimide, or polyphenylene sulfide. For example, the printed circuit 12 may be a copper wiring pattern formed on the base layer 11, etc.

In the present embodiment, the electromagnetic shielding film 1 is bonded to the printed wiring board 20 with the adhesive layer 3 facing the cover lay 14. As shown in FIG. 2, the second metal layer 6 mainly comprised of copper is located on the printed wiring board 20 side (i.e., on the inner side in the thickness direction X of the electromagnetic shielding film 1, on the adhesive layer 3 side bonded to the printed wiring board 20), and the first metal layer 5 mainly comprised of nickel is located on the opposite side from the printed wiring board 20 (i.e., on the outer side in the thickness direction X of the electromagnetic shielding film 1, which is the opposite side from the adhesive layer 3 side).

As described above, of the first and second metal layers 5, 6 that form the shielding layer 2, the second metal layer 6 mainly comprised of copper and having low magnetic permeability is located on the printed wiring board 20 side. Most of the magnetic field emitted from the printed circuit 12 is therefore reflected back to the printed circuit 12 by the second metal layer 6. The possibility of degradation in high frequency signal transmission characteristics can thus be reduced or eliminated.

Next, a manufacturing method of the shielded printed wiring board 30 will be described. The electromagnetic shielding film 1 is placed on the printed wiring board 20 and is heated and pressed with a press machine. A part of the adhesive layer 3 softened by the heating flows into the openings 15 in the cover lay 14 by the pressing. The electromagnetic shielding film 1 is thus bonded to the printed wiring board 20 via the adhesive layer 3, and the shielding layer 2 is connected to the printed circuit 12 of the printed wiring board 20 via the conductive adhesive. The shielding layer 2 is thus connected to the printed circuit 12.

The above embodiment may be modified as follows.

In the above embodiment, the electromagnetic shielding film 1 is provided on one surface of the printed wiring board 20 including the printed circuit 12. However, as shown in a shielded printed wiring board 40 of FIG. 3, the electromagnetic shielding film 1 may be provided on both surfaces of the printed wiring board 20. That is, in the present invention, the electromagnetic shielding film 1 shown in FIG. 1 can be bonded to at least one surface of the printed wiring board 20 via the adhesive layer 3.

### EXAMPLES

The present invention will be described below based on examples. The present invention is not limited to these examples. These examples may be modified or varied without departing from the spirit and scope of the present invention, and such modifications and variations are not intended to be excluded from the scope of the invention.

### Example 1

<Manufacture of Electromagnetic Shielding Film>

A 60 μm thick PET film having its surface subjected to release treatment was used as a support base material. The support base material was coated with a protective layer composition (solid content: 30 mass %) comprised of a bisphenol A epoxy resin (made by Mitsubishi Chemical Corporation, jER1256) and methyl ethyl ketone and was heated and dried to produce a support base material with a 5 μm thick protective layer.

A shielding layer was then formed on a surface of the protective layer. More specifically, a first metal layer was formed by placing the support base material with the protective layer in a batch vacuum deposition system (made by ULVAC, Inc., EBH-800), evacuating the system to an ultimate vacuum of 5×10⁻¹ Pa or less in an argon gas atmosphere, and depositing nickel to a thickness of 4.0 μm by magnetron sputtering (DC power output: 3.0 kW).

Subsequently, a second metal layer with a thickness of 2.0 μm was formed by placing copper on an evaporation boat, evacuating the system to an ultimate vacuum of 9.0×10′ Pa or less, and then heating the evaporation boat to perform vacuum deposition. The first metal layer and the second metal layer were successively formed so that there is no contact with the atmosphere between the sputtering and the deposition.

Thereafter, an adhesive layer with a thickness of 15 μm was formed by coating a surface of the shielding layer with an anisotropic conductive adhesive containing 100 mass parts of a cresol novolac epoxy resin (made by DIC Corporation, EPICLON N-655-EXP) and 20 mass parts of dendritic silver-coated copper powder (average particle size: 13 μm).

<Production of Shielded Printed Wiring Board>

Subsequently, the produced electromagnetic shielding films were placed on a printed wiring board with the adhesive layer of each electromagnetic shielding film facing the printed wiring board so that the second metal layer mainly comprised of copper was located on the printed wiring board side and the first metal layer mainly comprised of nickel was located on the opposite side from the printed wiring board. The stack of the electromagnetic shielding films and the printed wiring board was heated and pressed at 170° C. and 3.0 MPa for one minute with a press machine and was then heated and pressed at the same temperature and pressure for three minutes, and the support base materials were separated from the protective layers. A shielded printed wiring board having the electromagnetic shielding film on both surfaces of the printed wiring board was thus produced.

The printed wiring board had, on each side thereof, two copper foil patterns separated from each other and extending parallel to each other and an insulating layer of polyimide (thickness: 25 μm) covering the copper foil patterns, and the insulating layer had openings (diameter: 1 mm) exposing each copper foil pattern. The adhesive layers of the electromagnetic shielding films were placed on the printed wiring board such that these openings were completely covered by the electromagnetic shielding films.

<Electric Field and Magnetic Field Shielding Characteristics>

First, electric field and magnetic field shielding characteristics of the shielding film were evaluated by a KEC method using an electromagnetic shielding effect measuring apparatus (an apparatus comprised of an electric field shielding effect evaluation apparatus 11a and a magnetic field shielding effect evaluation apparatus 11b) developed by KEC Electronic Industry Development Center.

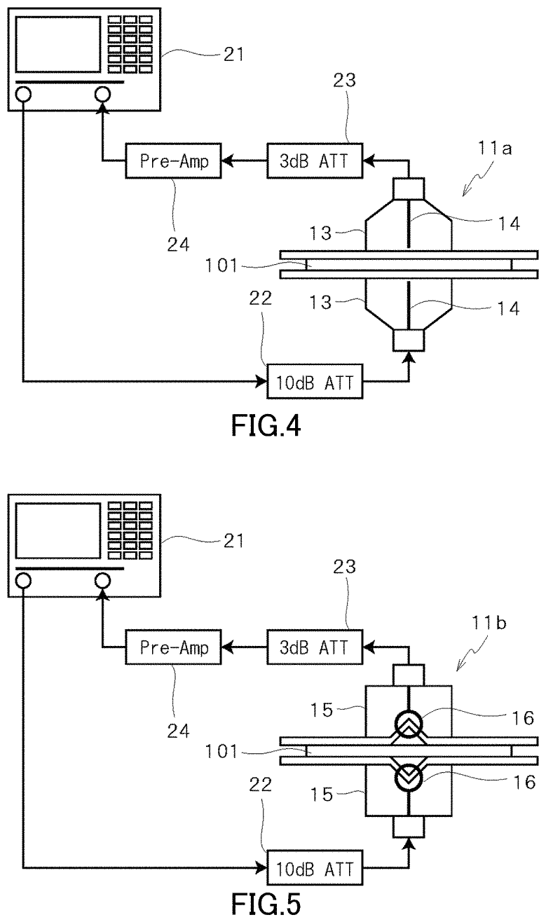

FIGS. 4 and 5 are diagram showing the configuration of a system that is used in the KEC method. The system that is used in the KEC method is formed by the above electromagnetic shielding effect measuring apparatus, a spectrum analyzer 21, a 10 dB attenuator 22, a 3 dB attenuator 23, and a preamplifier 24.

U3741 made by ADVANTEST CORPORATION or HP8447F made by Agilent Technologies, Inc. was used as the spectrum analyzer 21. As shown in FIGS. 4 and 5, different jigs (measurement jigs 13, 15) were used to measure electric field shielding characteristics and magnetic field shielding characteristics.

In the electric field shielding effect evaluation apparatus 11a, two measurement jigs 13 are disposed so as to face each other. A shielding film (measurement sample) 101 to be measured was held between the two measurement jigs 13. The measurement jigs 13 are sized in accordance with a TEM cell (Transverse Electro Magnetic Cell) and are symmetrically divided along a plane perpendicular to the direction of their transmission axis. In order to prevent formation of a short circuit by insertion of the measurement sample 101, flat plate-like center conductors 14 were placed so as to be spaced apart from the measurement jigs 13.

In the magnetic field shielding effect evaluation apparatus 11b, two measurement jigs 15 are disposed so as to face each other. The shielding film 101 to be measured was held between the two measurement jigs 15. In order to generate an electromagnetic field with a large magnetic field wave component, the magnetic field shielding effect evaluation apparatus 11b uses shielded circular loop antennae 16 for the measurement jigs 15, and each shielded circular loop antenna 16 is combined with a metal sheet with a 90 degree bend so that one fourth of each loop antenna is exposed to the outside.

In the KEC method, an output signal from the spectrum analyzer 21 is first input to the measurement jig 13 or the measurement jig 15 on the transmitting side via the attenuator 22. The signal is then received by the measurement jig 13 or the measurement jig 15 on the receiving side and passes through the attenuator 23. The signal having passed through the attenuator 23 is then amplified by the preamplifier 24. The level of the resultant signal is measured by the spectrum analyzer 21. The spectrum analyzer 21 outputs the amount of attenuation obtained in the case where a shielding film is placed in the electromagnetic shielding effect measuring apparatus with respect to the amount of attenuation obtained the case where no shielding film is placed in the electromagnetic shielding effect measuring apparatus.

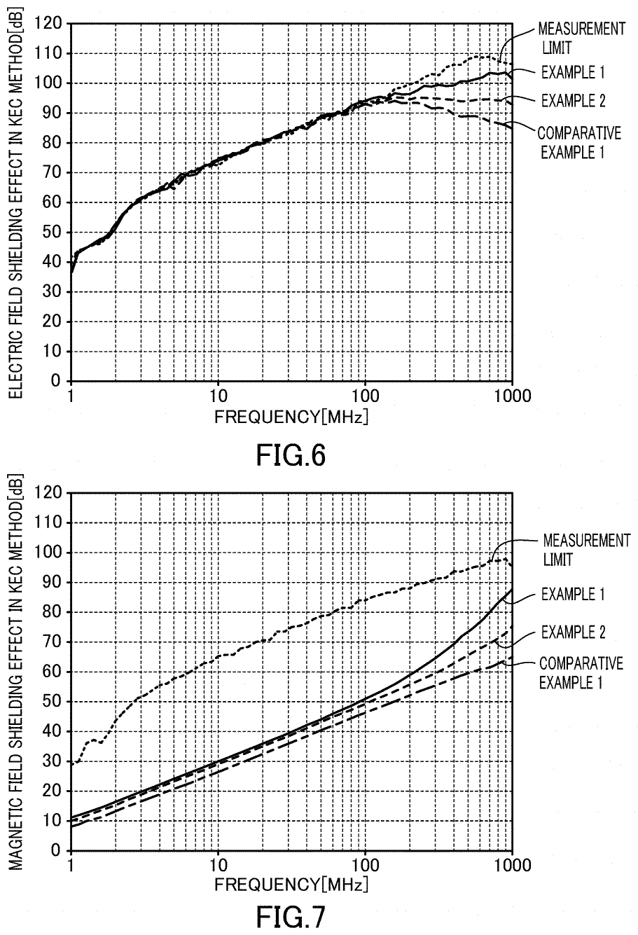

Electric field shielding performance and magnetic field shielding performance of the produced shielded printed wiring board were evaluated by using this electromagnetic shielding effect measuring apparatus. FIG. 6 shows the measurement results of the electric field shielding performance, and FIG. 7 shows the measurement results of the magnetic field shielding performance. The produced shielded printed wiring board was cut into 15 cm squares, and these square pieces were used as measurement samples. The measurement was carried out in the frequency range of 1 MHz to 1000 MHz in an atmosphere with a temperature of 25° C. and relative humidity of 30 to 50%.

<Output Waveform Characteristics>

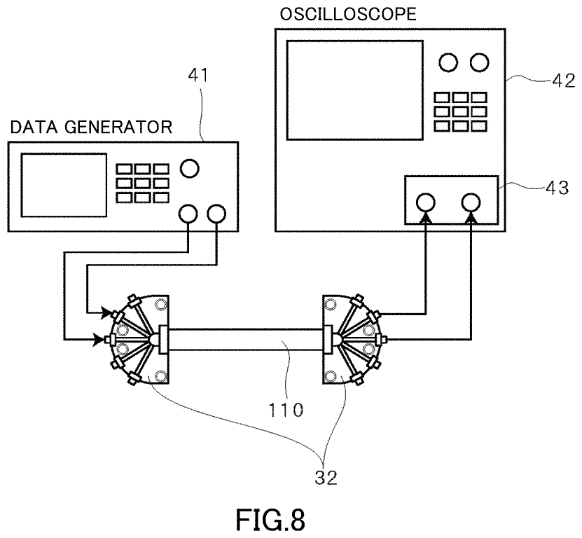

Next, output waveform characteristics of the shielding film were evaluated by using a system configuration shown in FIG. 8. This system is formed by a data generator 41, an oscilloscope 42, a sampling module 43 mounted on the oscilloscope 42, and a pair of connection substrates 32.

81133A made by Agilent Technologies, Inc. was used as the data generator 41. DSC8200 made by TEKTRONIX, INC. was used as the oscilloscope 42. 80E03 made by TEKTRONIX, INC. was used as the sampling module 43.

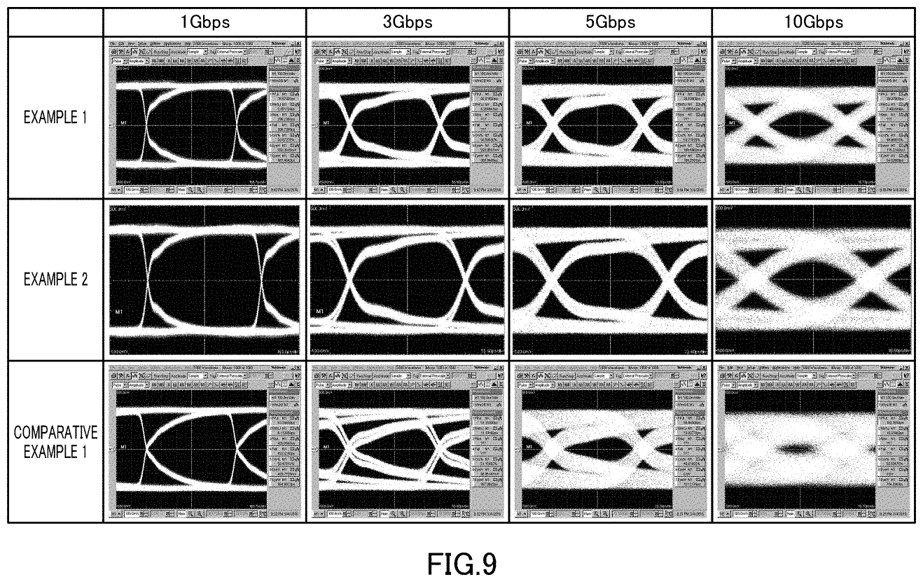

As shown in FIG. 8, each connection substrate 32 has an input terminal and an output terminal. A shielded flexible printed wiring board 110 to be measured was connected and supported between the pair of connection substrates 32 so as to extend straight and to be suspended in the air. The shielded flexible printed wiring board 110 was also connected to the data generator 41 and the sampling module 43, and an eye pattern was observed. FIG. 9 shows the measurement results for bit rates of 1 Gbps, 3 Gbps, 5 Gbps, and 10 Gbps observed by the oscilloscope 42.

The output waveform characteristics were measured by using the measurement samples used for the measurement of the frequency characteristics described above. The input amplitude was 150 mV/side (300 mVdiff) and the data pattern was PRBS23. The measurement was carried out in an atmosphere with a temperature of 25° C. and relative humidity of 30 to 50%.

### Example 2

An electromagnetic shielding film and a shielded printed wiring board were produced in a manner similar to that of Example 1 except that the thickness of the first metal layer comprised of nickel was changed to 2 μm, and electric field and magnetic field shielding characteristics and output waveform characteristics were evaluated. The results are shown in FIGS. 6, 7, and 9.

### Comparative Example 1

An electromagnetic shielding film and a shielded printed wiring board were produced in a manner similar to that of Example 1 except that the first metal layer (thickness: 2 μm) was comprised of copper and the second metal layer (thickness: 4 μm) was comprised of nickel, namely except that the first metal layer and the second metal layer were switched from Example 1, and electric field and magnetic field shielding characteristics and output waveform characteristics were evaluated. The results are shown in FIGS. 6, 7, and 9.

As shown in FIGS. 6 and 7, the amount of attenuation is larger in the shielded printed wiring boards of Examples 1 and 2 than in Comparative Example 1 and therefore the shielded printed wiring boards of Examples 1 and 2 have better shielding characteristics than Comparative Example 1.

As shown in FIG. 9, in the shielded printed wiring boards of Examples 1 and 2, signals are less likely to be disturbed even at higher bit rates as compared to Comparative Example 1 and therefore the shielded printed wiring boards of Examples 1 and 2 have better high frequency signal transmission characteristics than Comparative Example 1.

### INDUSTRIAL APPLICABILITY

As described above, the present invention is suitable for electromagnetic shielding films and shielded printed wiring boards including the same.

The above description of the specific embodiments of the present invention is given for illustrative purposes only and is intended neither to be comprehensive nor to limit the present invention to the described embodiments. It is to be understood by those skilled in the art that numerous modifications and variations can be made based on the above description.

### DESCRIPTION OF REFERENCE CHARACTERS

1 Electromagnetic Shielding Film
2 Shielding Layer
3 Adhesive Layer
4 Protective Layer
5 First Metal Layer
6 Second Metal Layer
12 Printed Circuit
20 Printed Wiring Board
30 Shielded Printed Wiring Board
40 Shielded Printed Wiring Board

1. An electromagnetic shielding film including a shielding layer that is formed by a first metal layer mainly comprised of nickel and a second metal layer mainly comprised of copper, an adhesive layer formed on the second metal layer side of the shielding layer, and a protective layer formed on the first metal layer side of the shielding layer which is an opposite side of the shielding layer from the second metal layer side, characterized in that
the first metal layer has a thickness of 2 μm or more and 10 μm or less, and the second metal layer has a thickness of 2 μm or more and 10 μm or less.

2. The electromagnetic shielding film of claim 1, characterized in that a sum of the thickness of the first metal layer and the thickness of the second metal layer is 4 μm or more and 20 μm or less.

3. The electromagnetic shielding film of claim 1, characterized in that the adhesive layer is an anisotropic conductive adhesive layer.

4. The electromagnetic shielding film of claim 1, characterized in that the electromagnetic shielding film is used for a signal transmission system that transmits frequency signals of 1 GHz to 10 GHz.

5. A shielded printed wiring board, characterized in that the electromagnetic shielding film of claim 1 is bonded to at least one surface of a printed wiring board including a printed circuit via the adhesive layer.
